(19) United States
(12) Patent Application Publication
(10) Pub. No.: US 2010/0187433 A1
(43) Pub. Date: Jul. 29, 2010

(54) IMPROVED PARTICLE BEAM GENERATOR

(75) Inventor: Derek Anthony Eastham, Chester Cheshire (GB)

Correspondence Address: SHUMAKER & SIEFFERT, P. A., 1625 RADIO DRIVE, SUITE 300, WOODBURY, MN, 55125, US

(73) Assignee: NFAB LIMITED, St. Asaph (GB)

(21) Appl. No.: 12/523,984

(22) PCT Filed: Jan. 24, 2008
(86) PCT No.: PCT/GB2008/050050

§ 371 Date: Mar. 18, 2010

(30) Foreign Application Priority Data
Jan. 25, 2007 (GB) 0701470.7
Apr. 25, 2007 (GB) 0707958.5
Jul. 11, 2007 (GB) 0713447.1
Aug. 10, 2007 (GB) 0715495.8
Sep. 14, 2007 (GB) 0717927.8

(51) Int. Cl. H01J 37/10; H01J 3/14

(52) U.S. Cl. 250/396 R

(57) ABSTRACT

A particle beam generator comprising particle extraction means disposed adjacent a particle source and operable to extract particles from such a source into an extraction aperture of the extraction means to form a particle beam, particle accelerating means operable to accelerate the extracted particles to increase the energy of the beam, and focussing means operable to focus the particle beam, each of said extraction means, accelerating means and focussing means being arranged in sequence and having apertures therethrough and in alignment to define a passageway through which the particles are constrained to move, characterised in that the extraction means comprises a lens structure comprising at least a pair of electrodes separated by a layer of insulating material allowing the application of different potentials to each of the lens structure electrodes, one of said electrodes comprising an extraction plate having an extraction aperture formed therein, by means of which extraction plate particles may be drawn from the particle source and through the extraction aperture by means of a potential difference between the source and said extraction plate.

This invention relates to an improved particle beam generator, and more specifically to a sub-miniature scanning electron microscope (SEM).

Although the following description relates in the main to scanning electron microscopes, it is to be mentioned that the application is considered to be of wider scope, and in particular relates to the production of electron and/or ion beams in general.

### BACKGROUND

In the applicant's earlier International Patent Application WO2003/107375 entitled, ‘A Particle Beam Accelerator’, a design for a sub-miniature electron (or ion) beam generator, ideal for a SEM, is described which is capable of focussing electrons (or ions) emanating from a nanotip at low energies (as little as 300 eV) down to atomic dimensions. In the case of a SEM, the substrate onto which the beam is focussed will be the specimen under examination, but other uses for the beam, and the manner in which it reacts with, is reflected by or adsorbed into the specimen are contemplated by both that application and the present application.

The earlier design was based on two fundamental principles. Firstly the overall size and focal length of the instrument was reduced to the micron range (typically less than 20 microns) and secondly, the electrons from the nanotip were prevented from expanding beyond about 100 nm diameter by applying a high electric field in close proximity to the nanotip from which the electrons (or ions) are extracted by field emission.

This microscope therefore works by directly imaging the emission sites (ion or electron) on a nanotip unlike a conventional large scale microscope which, because of aberrations requires much higher voltages and even then can only achieve the resolution by imaging an aperture in the system (which is illuminated by the electron/ion source).

One embodiment of the prior art arrangement is shown in FIG. 1 hereof which is a microscale arrangement of electrodes (in solid black) 3A-D which are separated by an insulating material (shaded grey), 2, both of which have aligned apertures thus providing a passageway through the whole assembly. It is to be noted in this arrangement that the outside diameter of the different constituent layers may be different from that defined along the line AB in which all the outer diameters are uniform. Essentially this is a multilayer thin film with a hole through it which defines the axis of the microscope and down which the electrons, 4, are accelerated and focussed at a point, 5, beyond the microscope. The distance to the focus is typically around 5 microns from the end electrode. The electrons are emitted by the nanotip, 1, if the potential between the extractor electrode 3A and the tip is sufficient. Typically one might have around −320 Volts (V1) on the nanotip and −300 Volts (V2) on the extractor electrode 3A to produce a 320 eV electron beam. The electrons pass through the hole (d1 is typically 30 nm for a tip axially distant from the electrode by about 30 nm but can be as large as d₂ (if the thickness of the first electrode, t, is increased) and are accelerated towards the second electrode because the potential on this is 0V (V3) so that there is a high field across the first insulating section which has a length “a” typically less than 3 microns. The electrons are also focused by the entrance lens and can then be formed into a narrow beam in section ACC, in which the beam diameter is typically less than 100 nm and passes into the section, MEZL, which is a microscale einzel lens. Typically this might have an aperture of 300 nm and with the electrode thicknesses, u, of around 300 nm and, v, around 400 nm. The thickness of the insulating sections, b and c, vary according to the total desired energy of the beam but typically for 300 eV electrons these are less than 3 microns. In this arrangement the voltages on the outer two electrodes, V3 and V5 is zero whilst the central electrode at V4 can be varied (typically) from −300 to +300 Volts for a 300 eV beam. Changing this voltage will, of course alter the position of the focal point of the electron beam.

One of the main disadvantages of this arrangement is that the entrance aperture focusing effect depends on the total energy of the electrons, V1, since the strength of the electric field is simply, V2−V3=V1+20 Volts. This means that one cannot have the same beam divergence or convergence into the microscale einzel lens at all energies and so the design can only be optimum for a particular energy.

Since in many applications it is desirable to make studies at different energies. It is an object of this invention to provide a sub-miniature SEM which is capable of accommodating different originating electron/ion beam energies without significantly altering the focal length of the beam or of needing to modify a relatively standard einzel lens structure.

### STATEMENTS OF INVENTION

According to a first aspect of the present invention there is provided a particle beam generator comprising: particle extraction means disposed adjacent a particle source and operable to extract particles from such a source into an extraction aperture of the extraction means to form a particle beam, particle accelerating means operable to accelerate the extracted particles to increase the energy of the beam, and focussing means operable to focus the particle beam, each of said extraction means, accelerating means and focussing means being arranged in sequence and having apertures therethrough and in alignment to define a passageway through which the particles are constrained to move, characterised in that the extraction means comprises a lens structure comprising at least a pair of electrodes separated by a layer of insulating material allowing the application of different potentials to each of the lens structure electrodes, one of said electrodes comprising an extraction plate having an extraction aperture formed therein, the extraction plate being arranged whereby particles may be drawn from the particle source and through the extraction aperture by means of a potential difference between the particle source and said extraction plate.

The provision of a multiple electrode extraction means immediately adjacent the particle source allows not only the extraction of particles into and through the aperture of the extraction means for subsequent delivery to the accelerating means of the device, but also permits some focussing effecting to be achieved in the relatively short length of the extraction means and for different beam energies because different potentials may be applied to each of the different electrodes in said extraction means.

Most preferably, the focussing means is an Einzel lens structure having an overall length of the order of from about 1 to about 10 μm.

Preferably the extraction means is a nano-scale Einzel lens structure (NEZL) have an overall length of no more than 500 nm, more preferably no more than 200 nm, and thus the particle beam generator as a whole consists of two Einzel lens structures, one at the front of the device and one at the rear, both of which are capable of providing differing degrees of control over the particle beam.

Preferably, the extraction means consists of two electrodes. Alternatively, the extraction means consists of three electrodes.

In an alternative embodiment, the particle beam generator includes a more standard extraction plate having extracting aperture therein and disposed sufficiently adjacent the particle source, and a nano-scale Einzel lens structure is disposed immediately behind said extraction plate so as to have immediate effect on particles having been extracted from the particle source thereby.

In a second aspect of the invention there is provided a particle beam generator comprising particle extraction means disposed adjacent a particle source and operable to extract particles from such a source into an extracting aperture within said extraction means to form a particle beam, particle accelerating means operable to accelerate the extracted particles to increase the energy of the beam, and focussing means operable to focus the particle beam, each of said extraction means, accelerating means and focussing means being arranged in sequence and having apertures therethrough and in alignment to define a passageway through which the particles are constrained to move, characterised in that the particle generator further includes a secondary focussing means disposed remotely from the end of the primary focussing means such that said primary and secondary focussing means are essentially separated, and having an average aperture size which is greater than that for the primary focussing means.

Preferably, the secondary focussing means is caused to be aligned coaxially with said primary focussing means by a technique such as nanopositioning which achieves a coaxiality between the two focussing means to within 10 nm, and most preferably to within 1 nm.

In a preferred arrangement, the first electrode of the secondary focussing means is provided with a knife-edged opening aperture which effectively collimates a particle beam arriving thereat and which is of greater diameter than said aperture.

Preferably, in any aspect of the invention, the particles are extracted from a cold field emission source using a nanotip. Such arrangement has been previously described in R. H. Fowler and L. Nordheim, Proc. Roy. Soc., A119 (1928) 173, but in a most preferred arrangement, the nanotip is coated with an insulating composition and a semiconductor composition, both being of the order of nanometers in thickness which serves to increase the output electron current of the nanotip and reduce the energy spread of the particle beam emitted therefrom. Preferably, a voltage is applied across the insulating layer by applying a negative voltage to the metal nanotip whilst connecting the semiconductor to earth.

Preferably, the simplest nanotip multilayer structure consists of a single insulating layer on the (metal) nanotip which is overlaid with a semiconductor and the voltage is adjusted so that the Fermi level in the metal is in-line with or near to the top of energy band gap in the semiconductor. The voltage can also be adjusted to initiate resonance electron tunnelling across the barrier and therefore increase the current output further whilst maintaining a narrow electron energy spread. Preferably, the thickness of the insulator and semiconductor are each in the range from 0.2 nm to 20 nm.

In an alternate arrangement, preferably the simple two-layer structure mentioned above is replaced with a multi-layer system comprising a metal nanotip and insulating and semiconducting layers provided thereon with different voltages across each insulating layer. The net aim of this is to transport electrons more efficiently using quantum tunnelling to electron states in the conduction band of the outer semiconducting layer where they can be emitted into the vacuum when a high field is applied to the tip. Preferably the thickness of the deposited layers is from 0.5 to 20 nm.

In a preferred arrangement, the nanotip (or particle source) is closely followed by a nanometre sized aperture and a high electric field accelerating section. Ideally, a voltage is applied to the nanotip (or particle source) so that electrons are emitted from the tip and pass through the aperture and are accelerated by the high field.

In some embodiments the distance from the particle source to said aperture is in the range from around 5 to around 500 nm, preferably around 50 nm. In some embodiments the distance is comparable to the aperture diameter. Thus, if the aperture size is increased, the distance from the particle source to the aperture is correspondingly increased.

Preferably, the strength of the electric field is such that the electron beam diameter is almost constant along the length of the accelerating section and is less than that of the aperture.

In this manner, it is possible to obtain a source which has almost no aberrations and thus preserves the intrinsic field emission properties of the nanotip.

In a preferred arrangement, the source is a nanotip which is sharpened by focussed ion beam (FIB) milling so as to reduce the area at the tip from which electrons can be emitted.

The aperture may be tapered or altered in a way so as to produce a lensing effect so as to further restrain expansion of the beam. Conical apertures may be employed to reduce scattering of electrons.

Most preferably the nanotip comprises a nanopyramid or similar stable electron emitter structure of atomic or substantially atomic dimensions. The structure may be provided at a free end of a conventional nanotip. The conventional nanotip may be a tungsten nanotip.

Fabrication of nanopyramidal and similar structures are described in the literature (see for example H.-S. Kuo et al, Jap. J. Appl. Phys. 45(11) (2006), page 8972; C. Schlossler et al., J. Vac. Sci. Technol. B15(4) (1997) page 1535; A. B. H. Tay and J. T. Thong Rev. Sci. Instr. 75(10) (2004) page 3248 and S. Minzuno J. Vac. Sci. Technol. B19(5) (2001) 1874).

Tay and Thong (see above paragraph) describe the formation of a nanotip from cobalt wire. It is possible to generate polarized electrons from such a nanotip, for magnetic studies of surfaces.

Nanopyramidal and similar structures described above may be made from gold, platinum, iridium, and combinations thereof. These metals are particularly useful because contaminants may be removed by heating. Heating to relatively low temperatures is sufficient to remove contaminants and allow formation of useful nanoscale electron sources. Other materials and combinations thereof are also useful.

In embodiments of the invention gold nanotips are particularly useful. This is at least in part because nanopyramids can be formed from gold at a lower temperature than nanopyramids formed from platinum or iridium.

Preferably the electrodes are formed from a metal. Preferably the metal is a metal that does not react with oxygen or other gases to form a contaminant such as metal oxide or any other contaminant capable of storing or otherwise supporting a charge thereon. Preferably the metal is a metal that can be cleaned of adsorbed gases and/or other contaminants under ultrahigh vacuum (UHV) conditions by moderate heating.

These features have the advantage that a buildup of charge on one or more of the electrodes may be reduced or substantially eliminated. This in turn has the advantage that a focussing and steering effect of one or more of the electrodes is not compromised substantially by the presence of charge on one or more of the electrodes.

The metal is preferably gold, platinum, iridium or a mixture thereof. Other metals are also useful.

The nanotip (which may also be described as a ‘supertip’) may be arranged to ionise gaseous species introduced into the environment of the tip.

The nanotip may instead or in addition be arranged to generate ions. In some embodiments this is achieved by feeding a solid or liquid species to the tip. For example, a liquid metal such as liquid gallium may be fed to the tip. The liquid species may be fed by a capilliary action from a reservoir.

The tip may be arranged in use to protrude from a surface of liquid contained in the reservoir. The reservoir may have means for heating the reservoir thereby to maintain a species contained in the reservoir in a liquid state.

The generator may be arranged to form a particle beam comprising ions generated by the nanotip. Thus, the generator may be arranged to form a particle beam comprising ions generated by ionising liquid gallium or any other suitable material supplied to the nanotip.

Throughout the description and claims of this specification, the words “comprise” and “contain” and variations of the words, for example “comprising” and “comprises”, means “including but not limited to”, and is not intended to (and does not) exclude other moieties, additives, components, integers or steps.

Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith.

### BRIEF DESCRIPTION OF THE DRAWINGS

For a better understanding of the present invention and to show how it may be carried into effect, reference shall now be made by way of example to the following drawings, in which:

FIG. 1 shows a schematic view of a particle beam generator according to the prior art configuration;

FIG. 2A shows a schematic view of a particle beam generator according to a first aspect of the invention and FIG. 2B shows a section of this microscope formed from a multilayer structure;

FIG. 3 shows a schematic view of a particle beam generator according to a second aspect of the invention;

FIG. 3B shows a schematic view of a microscope according to the invention;

FIG. 3C provides a more detailed view of the envelope of electron trajectories through the microscope of FIG. 3B;

FIGS. 4A & B show idealized geometries of uncoated and coated nanoprobes, shown greatly enlarged;

FIGS. 5 and 6a, b, c show respectively a schematic representation of the extraction of particles from a nanotip, and schematic representations of the nanotip geometry;

FIG. 6d provides a graph demonstrating the variation in beam spot diameter with the differential potential between the first accelerating plate and the nanotip;

FIG. 7 is a schematic drawing of a scanning electron microscope when employed to carry out a particularly useful method;

FIGS. 8a, b, c are schematic drawings of the scanning electron microscope of FIG. 7 adapted to measure scattered electron intensity and energy, together with schematic indications of energy intensities of reflected electrons;

FIGS. 9a, 9b are respectively a schematic drawing of a method for improving resolution of a scanning electron microscope; and schematic representations of the signals representative of reflected electrons at different detectors;

FIG. 10 is a schematic drawing of a scanning electron microscope of FIG. 7 adapted to study the crystal structure of material;

FIG. 11 shows a microscope according to an embodiment of the invention;

FIG. 12 shows a section of the embodiment of FIG. 11;

FIG. 13 is a perspective view of a microscope according to an embodiment of the invention; and

FIG. 14 is a plan view of a pair of atomically sharp pyramidal nanotips.

### DETAILED DESCRIPTION

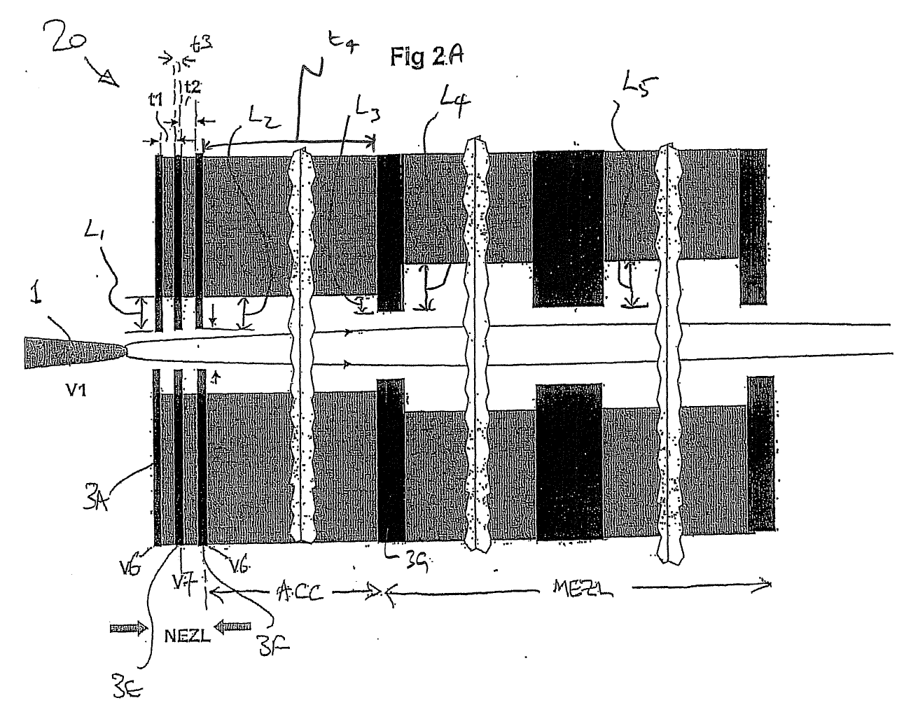

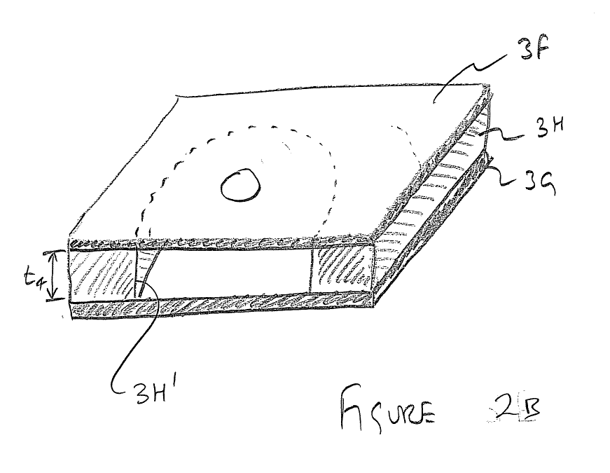

Referring firstly to FIG. 2, there is shown a particle beam generator 20 comprising a nano-scale Einzel lens structure NEZL, accelerating means ACC and a more standard Einzel lens structure MEZL. The NEZL section is disposed immediately adjacent the particle source or nanotip 1 as shown in FIG. 2. The NEZL section has a total thickness typically less than 200 nm so that the beam does not expand significantly. The aperture in each of the electrodes is typically around 50 nm and the voltage, V7, can be adjusted in the range from −50 to +50 Volts when the thickness of the insulators t1 and t2, is 50 nm for electrodes of similar thickness t3, which is ideally between 10-60 nm. Altering this voltage, V7, changes the beam divergence or convergence into the subsequent accelerator and microscale einzel lens (MEZL) sections of the device and so it is possible to constrain the exiting particle beam to have the same properties irrespective of the overall particle energy. In some embodiments of the invention the NEZL lens is not included.

A variant of the arrangement shown is considered where only a single extra electrode is used is also possible. Thus the third downstream electrode at V6 volts is removed and again the voltage V7 is varied from −50 to +50 Volts.

With this nanoscale einzel lens in place, the length of the accelerating section, ACC, is then made such that when operating at the highest voltages, the electric field (in the first insulator of thickness t4) is significantly less than its breakdown strength.

In some preferred embodiments of the invention, insulator layers comprised in the ACC, NEZL and MEZL portions are undercut in order to electrically screen the electron beam from charge that may accumulate in or on one or more of the insulator layers.

The presence of undercut of the insulator layers depth L with respect to conducting plates of the structure is indicated in the schematic diagram of the embodiment of FIG. 2. The magnitude of undercut L is arranged to correspond to a ratio of undercut to insulator thickness, L/t of around 3:1. Other ratios are also useful, including 2:1 and 1:1, in this and other embodiments of the invention.

In FIG. 2, undercut of the insulator layers comprised in the ACC portion is indicated to be of depth L₁ Undercut of the corresponding layers of the NEZL portion is indicated to be one of depth L₂ or L₃. Undercut of the corresponding layers of the MEZL portion is indicated to be one of depth L₄ or L₅.

In some embodiments of the invention, the structure of FIG. 2A is formed by etching a hole through a multilayer structure. A portion of such a multilayer structure is shown in FIG. 2B, reference signs is FIG. 2B corresponding to those of FIG. 2A. A passageway for the electron beam to pass through the structure is formed by etching of the hole.

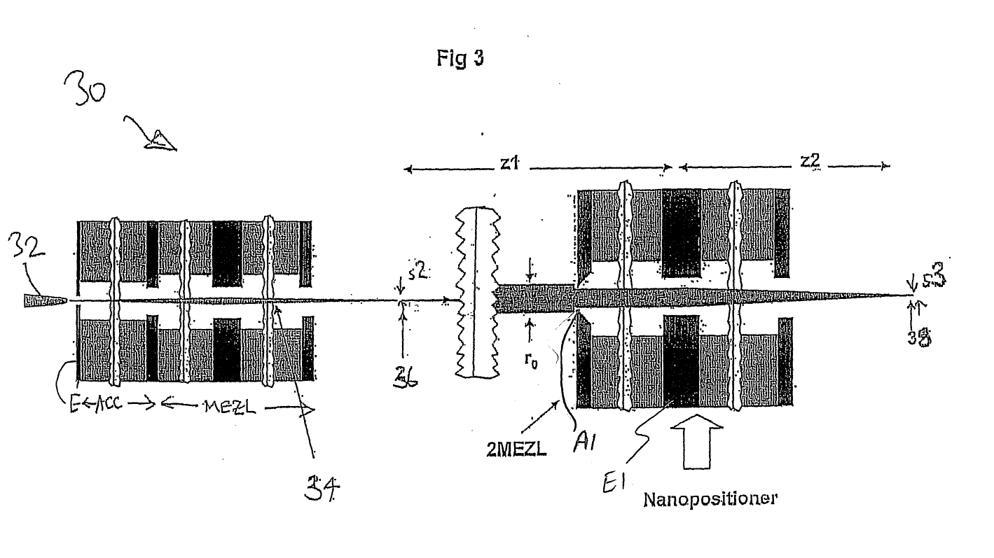

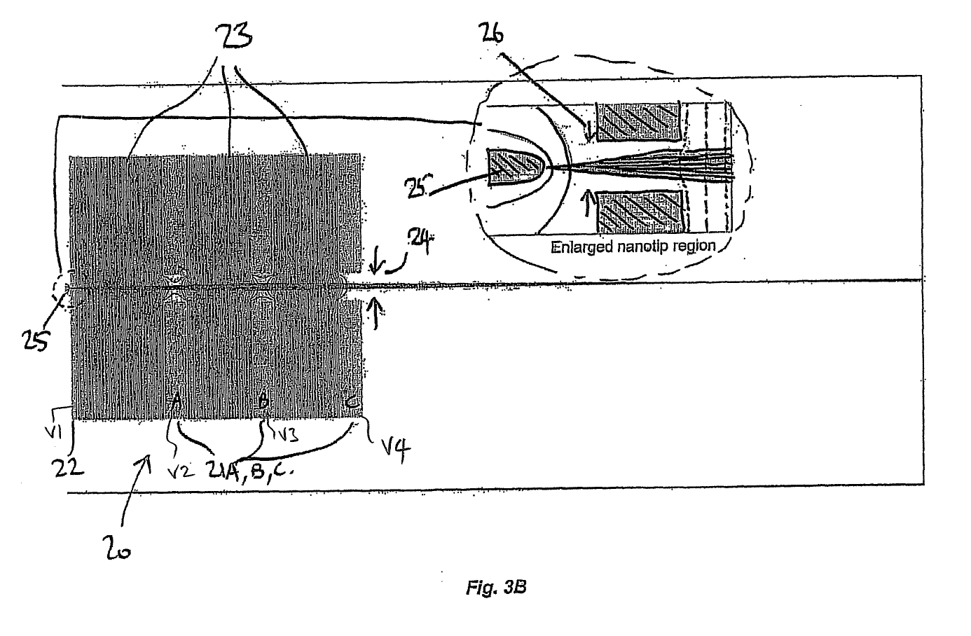

In some embodiments, the passageway is formed by a reactive ion etch (RIE) process. In some embodiments of the invention, undercut of the insulator layers is provided by etching a portion of each insulator layer starting from a free edge of the structure after the passageway has been formed (e.g. free edge 3H′, FIG. 2B). FIG. 2B shows a portion of the structure of FIG. 2A following etching of insulator layer 3H (FIG. 2, FIG. 3E) situated between electrodes 3F and 3G.

In other words, the insulator layer is etched in a lateral direction parallel to a plane of an insulator layer, along a direction toward the electron beam passageway formed in the structure, from a free edge of the structure. A region between conducting layers of the structure having no insulator layer is thereby formed, in a portion of the structure between the passageway and a free edge of the structure. In some embodiments, a diameter of a region etched to form recessed insulator layers may be in the range from about 5 μm to about 10 μm. Other diameters are also useful.

A further embodiment of the invention is shown in FIG. 3 which shows a particle beam generator 30 comprising a particle source 32 from which a particle beam 34 emanates, said generator having an extraction plate E, an accelerating section ACC, and a micro-scale einzel lens section MEZL also referred to as a primary focussing section.

The particle beam 34 emerges from an opposite end of the primary focussing section to the source 32 and travels through free space beyond the focal point of the primary focussing section, indicated at 36 in FIG. 3, whereafter the beam begins to expand in diameter to a diameter r₀. Accordingly, a secondary focussing means is provided in the form of a microscale electrostatic lens, 2MEZL, which is similar in all respect to the primary MEZL but can have an aperture somewhat larger than the first lens typically around 500 nm in diameter.

The 2MEZL lens is positioned to a high degree of accuracy (better than 1 nm) using commercially available nanopositioning equipment so that it is coaxial with the beam 34 from the particle beam generator as detailed in FIG. 3. If distance z1 between the focal point 36 and a first electrode E1 of the 2MEZL lens is sufficiently large, r₀ will be greater than the aperture diameter in the first electrode E1 of 2MEZL, and the beam will be collimated (see further description below) to a certain extent by the aperture A1 in extraction plate E. Thereafter, the remaining beam enters the lens where it is focused down to a spot, 38. The focal length of the second lens is z2 which is typically less than 10 microns.

It will be appreciated that the focal length can be varied by adjusting a value of the potential applied to electrode E1 (FIG. 3).

The entrance aperture A1 to this lens may be knife-edged as shown in the figure. In some embodiments a plain aperture may be employed provided the aperture does not intercept a portion of the beam thereby to block said portion. The aperture A1 to the secondary focussing means 2MEZL may be chosen such that it intercepts the particle beams (as shown in FIG. 3) thus reducing its phase space and allowing it to be subsequently focussed to a smaller spot.

The magnification which is z2/z1 is typically smaller than 0.1 (i.e. demagnification takes place) so that if z2 is 10 microns then z1 is larger than 100 microns. Thus the beam spot at 38, which has diameter s3, is related to the beam spot size at 36, which has diameter s2, by the simple relation s3=s2×z1/z2. Since it is relatively easy to produce nanometre spot sizes at 36 even when the nanotip is emitting nanoamperes of electrons then the beam spot size at 3 can be of atomic dimensions (Ångstroms).

However it should be should noted that, depending on the emittance of the beam, as discussed above it may be necessary to collimate the beam using the entrance aperture of 2MEZL thus resulting in a reduced current in the focused beam. This demagnification effect also means that any instability of lateral movement of the nanotip 32 (e.g. vibration) is decreased by the same amount. Thus lateral instability of the nanotip of 1 nm causes only lateral movements of around 1 Ångstrom at the final beam spot.

This second einzel lens 2MEZL also provides a convenient way in which the overall beam energy can be increased so as to further reduce the beam spot size since this varies as the square root of the beam energy. Thus one might typically have the beam exiting the first einzel lens MEZL at 300 eV and, by having all the electrodes in the first stage biased by an extra voltage of say −3000 Volts then the final energy will be 3300 eV. Thus the energy can be conveniently adjusted in the range from 300 to 3300 eV.

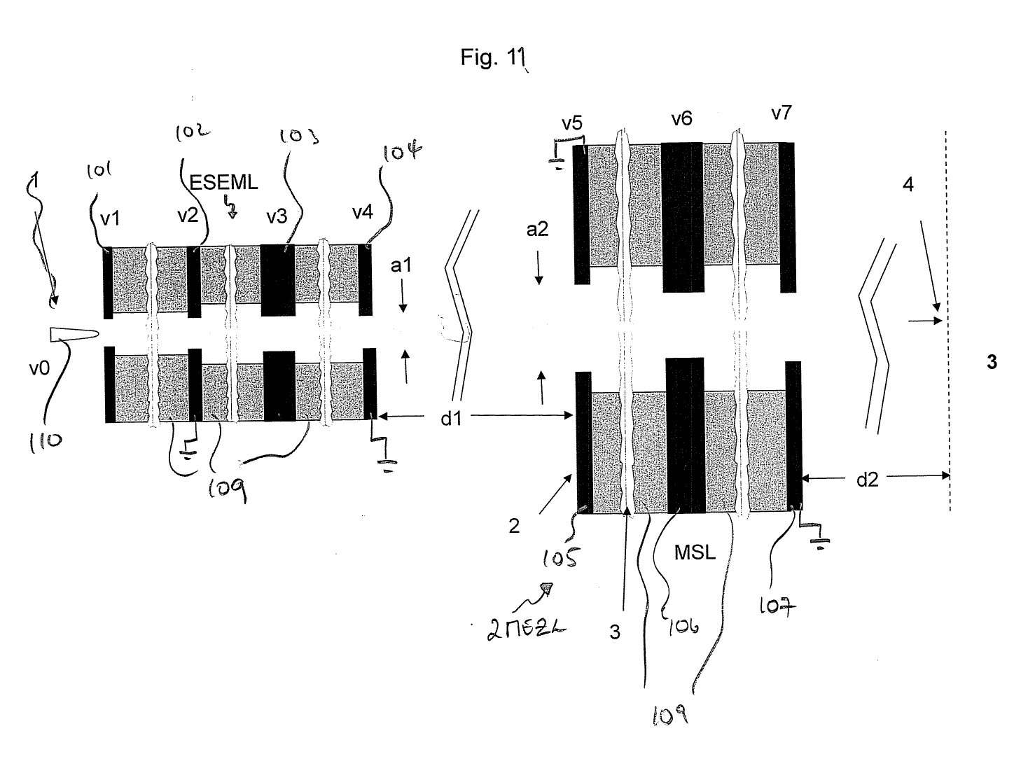

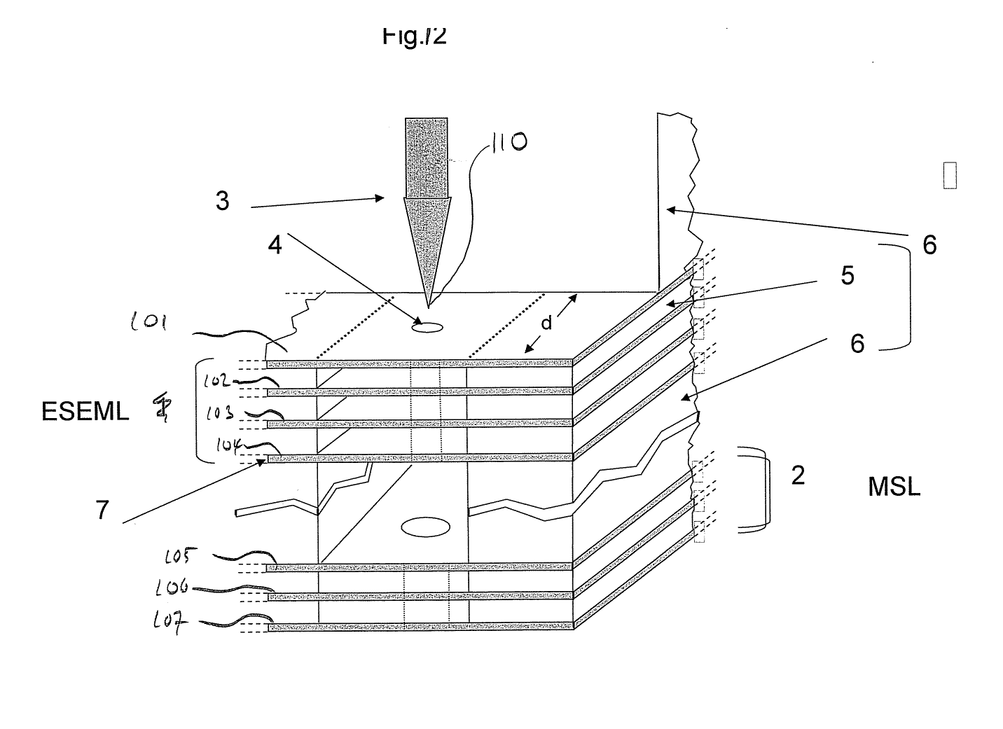

A further embodiment of the invention is shown in FIGS. 11 and 12. The embodiment is similar to that of FIG. 3 except that apertures in a 2MEZL portion of the structure are formed to be larger than a diameter of an electron beam to be passed through the apertures.

In the embodiment of FIGS. 11 and 12 apertures formed through components of the 2MEZL portion are formed to be of diameter a2 of from 1 μm to around 10 μm in diameter. An aperture formed in the first electrode 121 of the 2MEZL portion may be of a smaller or larger diameter to those formed in the remaining components of the 2MEZL portion.

As per the embodiment of FIG. 3, the ESEML portion (being a source/extractor/lens portion) is arranged to extract electrons from a source 101, in this embodiment an atomic emitter, to a beam spot size of atomic dimensions at a distance of around 6 mm from the end metal electrode 104 of the ESEML portion. The electron beam has an intensity of up to 1 nA and may be up to a million times brighter than conventional electron sources. The beam diameter may be less than 100 nm in some embodiments of the invention.

Electrodes 101, 102, 103, 104 are formed from a metallic material to a thickness of around 500 nm, whilst inter-electrode insulation layers 109 are formed to have a thickness of around 1 μm.

In use, in some embodiments a potential V0 of around −330V is applied to the nanotip 110 and a potential V1 of around −300V is applied to the first electrode 101 of the ESEML structure. Second and fourth electrodes 102, 104 are held at earth potential (V2, V4 respectively) whilst a positive or negative potential V3 is applied to third electrode 103, in the range of from around −300V to +300V. The potential V3 is selected so as to form a generally parallel beam of electrons.

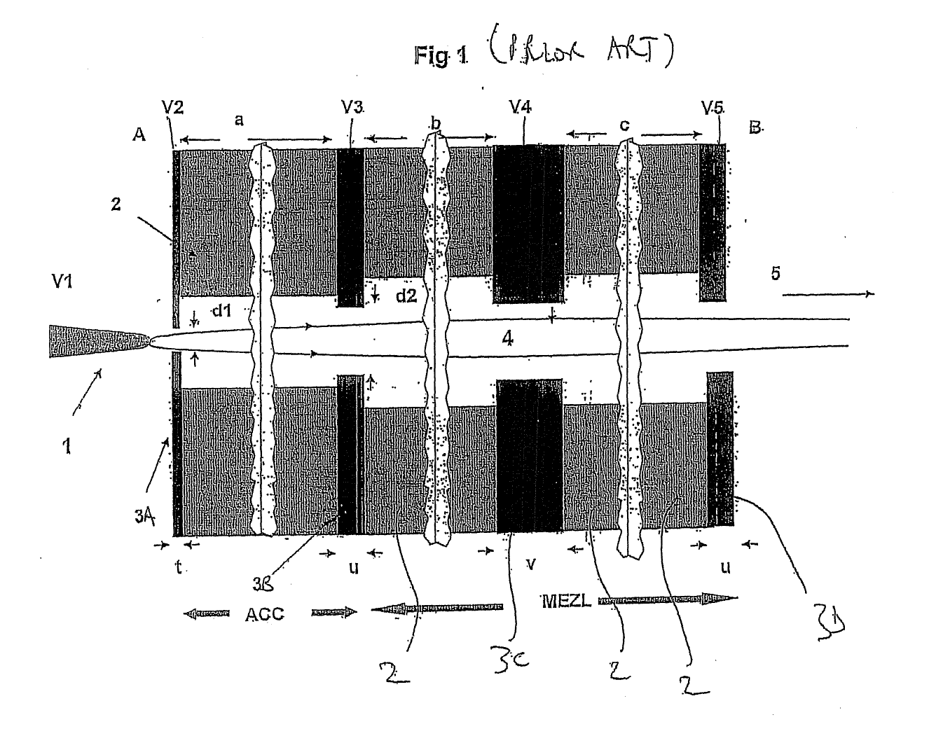

A secondary focusing portion 2MEZL is provided a distance d1 from the ESEML portion, d1 being around 100 μm in the embodiment of FIG. 1.

As per the ESEML portion, in the 2MEZL portion the electrodes 105, 106, 107 are formed to have a thickness of around 500 nm and inter-electrode insulation layers 106 are formed to have a thickness of around 1 μm.

Apertures formed in electrodes 101 to 104 are formed to be around 50 nm in diameter. In some embodiments the apertures are formed to be from around 50 nm to around 500 nm in diameter.

In use the apparatus of FIG. 11 is arranged whereby the distance d2 between a sample surface and a seventh electrode 107 being an end electrode of the structure is around 1 mm. Other distances are also useful. In some embodiments the distance is from around 10 nm to around 1 mm. In some embodiments the distance is from around 1 μm to around 100 μm.

In some embodiments this is achieved by maintaining fifth and seventh electrodes 105, 107 at earth potential and adjusting a potential V6 of sixth electrode 106.

In some embodiments of the invention the particle source 32 (FIG. 3) or 1 (FIG. 2A) is located a distance from the nearest aperture of the apparatus of from around 50 nm to around 500 nm. The distance may depend on the size of the aperture.

A third aspect of the invention is also covered hereby wherein the particle source (having a nanotip 1, 32) is cooled down to very low temperatures using liquid helium. This lowers the emittance of the tip by a factor which is proportional to the square root of the temperature in degrees Kelvin. Thus if the temperature is reduced to 4 K (the temperature of liquid helium) and the ambient temperature is 300 K then the emittance is reduced by a factor ( 4/300)½=0.115 and correspondingly the final beam spot is decreased by the same factor. Accordingly, in a third aspect of the invention, there is provided a particle beam generator having a nanotip or particle source cooled substantially below ambient room temperature, preferably by at least 100K, and further preferably by 150K, and yet further preferably by 200K. Most preferably, the particle source is cooled by liquid Helium to an approximate temperature of 4K.

In connection with the high-brightness nanotip aspect of the invention, a known common way of generating a bright source of electrons uses an extremely sharp metal needle which is placed in a high electric field. The sharp point enhances the electric field at the tip and this causes electrons to be emitted from the tip. This process is well known and a physical explanation for this behaviour was published by Fowler and Nordheim (see reference provided above). The amount of current which is emitted at room temperature depends on the strength of the applied electric field and the sharpness of the tip, where the sharpness is defined as the radius at the extreme end.

With the advent of near field microscopes such as the Scanning Tunnelling Microscope (STM) it has been possible to produce ‘needles’ or nanoprobes with extremely small radii tips known generally as nanotips. This has meant a radical improvement in the amount of current that can be emitted from a nanoprobe. Also the brightness of the source depends on the size of the area at the end of the nanotip from which the electrons are emitted. Here brightness is defined as the amount of current which can be emitted from a given area with a given angular divergence. The brightness of a source increases for a given current at a given energy for decreases both in the area and the angular divergence. Furthermore an important quality factor for the source is the energy spread of the electrons from the source. If the source is used as the primary supply of electrons in a scanning electron microscope, particularly one working at low energies (say below 5 keV energy) then the spread might be the determining factor in the ultimate resolution of the instrument.

A radical way to both improve the brightness and reduce the energy spread from the nanotip is to use a clean nanotip preferably made from (but not exclusively) metal. Such a nanotip can have a diameter of as little as 8 nm but this limiting size is reducing as improvements in the technology to make these instruments advances. The nanotip, which can be cleaned in-situ, is then coated (preferably in vacuum) with thin layers, nanometres thick, of different materials. The end result is a thin film multilayer which extends from the nanotip end to the body of the nanoprobe. In the simplest design the multilayer consists of an insulating layer vacuum deposited (e.g. silica or alumina) on the metal tip and then a second layer of a semiconductor deposited on top of this layer. Each layer would be of the order of a few nanometres thick. The layering is extensive enough to allow an electrical connection to be made to the semiconductor so that a voltage can be applied across the insulating layer. The easiest way this can be done is by connecting the semiconductor (doped or intrinsic) to an earth potential and to apply a negative potential (up to around 20 volts) to the metal centre. The source is operated by placing the nanoprobe in a high electric field so that the field at the nanotip is highly enhanced and then applying a negative voltage to the metal body of the nanoprobe. The field across the insulator (from this voltage) then causes electrons to pass through the insulator by the process of quantum tunnelling and into the conduction band of the semiconductor. Because these electrons are much closer to the zero energy of the vacuum they can then very easily tunnel through the barrier to the outside and be accelerated by the applied field. (Modern Semiconductor Device Physics, S. M. Sze (Edt.), Wiley and Sons, 1998, ISBN 0-471-15237-4 describes how the barrier to the vacuum beyond the semiconductor is generated and how the tunnelling current depends on the strength of the applied field and the energy difference between the electron in the metal, or in this case, the semiconductor, and the zero energy level of the vacuum.)

Furthermore it is also possible to routinely produce supertips (C. Schössler, J. Urban and H. W. Kroops, J. Vac. Sci. Technol. B15(4) (1997) 1535-1538) where the field emission sites are of atomic dimensions. If such tips can be employed with the present invention then the first stage alone will give a focussed beam spot of atomic dimensions-similar to the emission sizes. These tips are stable in air when employed to generate ions by field-ionization. Thus changing the polarity of all the voltages on the microscope will enable one to focus low energy beams (100-600 eV) down to atomic dimensions. Such an arrangement is known as a scanning focussing field-ion microscope. (SFFM).

Although this is a distinct improvement particularly with regard to reducing the energy spread of the electrons from the source since it can be arranged so that they can only be emitted from the bottom of the conduction band of the semiconductor the reduced quantum tunnelling currents may lead to a reduced total current. However it is possible to adjust the voltage and the thickness of the multilayers so that the tunnelling is resonant. This process has been exploited in thin film devices for electronics. If the voltages and thickness are carefully controlled then the transmission of electrons through the double barrier to the vacuum can be close to unity (100%). This resonant tunnelling occurs only at a particular voltage corresponding to a particular (binding) energy in the conduction band of the semiconductor. The energy spread of the electrons emitted from the tip is therefore much smaller than for an uncoated nanotip.

It will be appreciated that it is important that energy spread of the final beam is small. If the variation in beam energy were around 200 meV in some embodiments this would not result in excessive chromatic aberration since the beam diameter is small.

Furthermore this resonant tunnelling will only occur at points on the tip where the semiconducting layer is a given thickness. This may be a much smaller region on the nanotip than for an uncoated tip because the deposition process will produce the thickest layer in a much smaller region. Thus the brightness of the source is considerably increased.

Referring to FIG. 3B, there is shown a microscope 20 consisting of three 250 nm thick metal layers 21A-C and one 50 nm layer 22 separated by micron thick insulators 23 and with a 300 nm aperture 24. The nanotip 25 is placed 30 nm from the first electrode which has a 30 nm diameter hole 26 therein. The voltages are: nanotip, −515V; electrode 1 (labelled 22), −500V; electrode 2 (labelled 21A), 0V; electrode 3 (labelled 21B), −365V; and electrode 4 (labelled 21C), 0V. This produces a beam spot of the same size as the emission site (1.0 nm) and so the magnification is 1.

FIG. 3C shows the electron beam profile defined by a ray tracing program such as SIMION™. The types of calculation involved reproduce a Gaussian beam and are exact unless the beam is collimated in which case diffraction must then be considered. In the present invention, the beam is always very much smaller than the aperture in the microscope—the fill factor is always less than 20% and much smaller than this for atomic emitters—so the diffraction limit is determined solely by the electron wavelength whereas in conventional systems diffraction at apertures can be a limitation to the ultimate resolution. The starting point of the rays is the phase-space at the tungsten nanotip, which in this embodiment has a radius 5 nm, and was approximated by a rectangle of 8 points on the periphery (as defined by the full width of the Gaussian beam) of the occupied phase-space with the size of the emitting area being 1×1 nm and the full angle of emission being 6°, a figure extrapolated from prior art measurements on supertips (as, e.g. disclosed in Hong-Shi Kuo, Ing-Shouh Hwang, Tsu-Yi Fu, Yu-Chun Lin, Che-Cheng Chang and Tien T. Tsong, Jap. J. of Appl. Phys. 45 (11) (2006) 8972, C. Schlossler, J. Urban and H. W. P. Koops, J. Vac. Sc. Technol. B15(4) (1997) 1535, A. B. H. Tay and J. T. Thong, Rev. Sc. Instr. 75(10) (2004) 3248, and Seigi Minzuno, J. Vac. Sc. Technol., B19(5) (2001) 1874). The emission energy is assumed to be 4 eV.

The figure shows the beam profile defined by these rays for a point source and a nanometre sized emitter, positioned 60 nm from the first aperture, for a beam energy of 515 eV. Extractor plate 22 is maintained at a potential V1=−500 V. Electrodes 21A and 21C are maintained at a potential of 0V (i.e. V2, V4 are 0V) whilst electrode 21B is maintained at a potential V3=−380V.

These conditions produce beam spots of 0.04 nm and 1.24 nm at a distance of 4.9 μm from the end of the microscope. The beam spot size can be reduced by increasing the voltage on the einzel lens so that at around 4 μm from the end the beam spot sizes are 0.03 and 0.9 nm respectively. This is the approximate position of unit magnification. The ray traces for the point sized emitter show that the aberrations are much smaller than the diffraction limit of λ/2=0.5 Å.

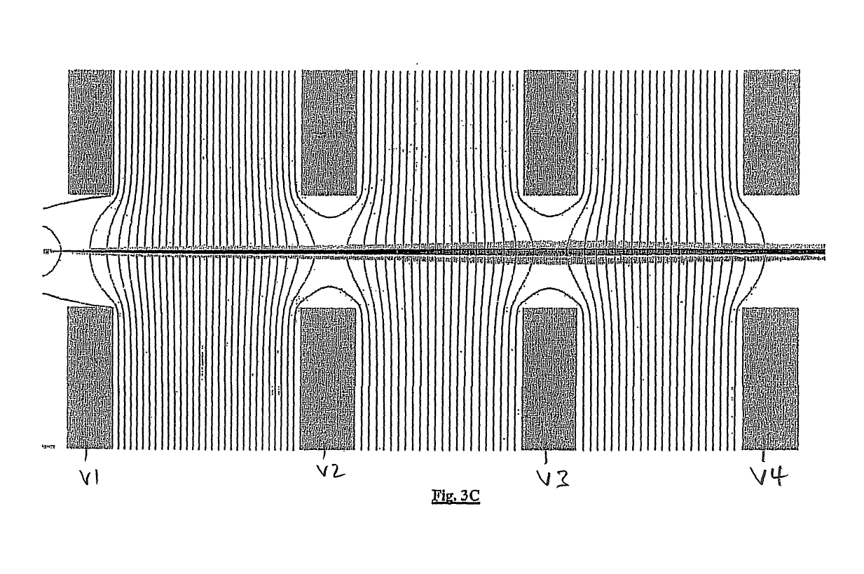

FIGS. 4A & 4B shows an idealized geometry of an uncoated and coated nanoprobe where each consists of a (metal) needle shaped object with an extremely sharp tip, (nanotip) which is shown highly enlarged. The nanoprobe shaft, 41, 42, is large enough so that it can be attached to a cantilever arm and electrical contacts can be made to the outer thin film. (The diagram for each nanoprobe is separated to show the two parts have a vastly different scale) The uncoated nanprobe, 41, has a nanotip, 43, with diameter of around 8 nm or greater. The new electron source nanoprobe, 42, is coated with an insulating layer, 45, and this is then overlaid with a semiconducting layer, 46, to which electrical contact can be made via the body of the nanoprobe. The metal body of the nanoprobe is electrically isolated and connected to a negative voltage supply, 47, through the shaft of the nanoprobe, 42, and an earth contact is made to the semiconducting outer layer 46 at a point on the nanoprobe surface, 48. If this coated nanoprobe is place in a high electric field with the body of the probe along the field direction (with the direction of the field being from the tip to the nanoprobe shaft) then electrons 49 can be emitted from the nanotip 44 when a negative voltage is applied across the insulating film 45. These electrons arise in the metal and tunnel through the insulating film into the semiconductor conduction band and thence into the vacuum.

As previously mentioned, in order to form a beam for use in electron microscopes (or lithography machines), the electrons are collected and focussed by a lens (usually electrostatic) immediately following an extraction aperture in front of the field emission tip (whether nanotip or otherwise). Thus the beam expands from the aperture and is re-focussed by this lens into a spot. The beam leaving this spot expands laterally but its expansion is reduced considerably be accelerating it to high voltages. A further lens or lenses (most often magnetic lenses) are then used to re-focus the beam to dimensions which can be as small as 1 nm. The voltages and sizes of the apertures are important in determining the performance of the instrument. In prior art systems, the aperture in front of the nanotip might have a dimension of the order of microns and is placed microns away from the aperture so that a few thousand volts is required to extract electrons from the nanotip. The aperture is arranged to be of a size generally equal to or larger than the tip: aperture distance along an axis of the lens immediately following the aperture. In some embodiments the aperture is much larger than the tip: aperture distance.

The lens immediately following the aperture is then used to refocus the electrons down to a small diameter before they are accelerated and focussed into a suitable beam spot for scanning electron microscopy (SEM) or other purposes.

In this case, and for electron beam lithography, the size of the spot and the intensity of the current is the factor determining the overall performance of the instrument. What is evident is that the overall performance of the microscope is limited by the brightness of the source. The brightness varies as the inverse of the square root of the energy and so is often quoted at a particular energy.

An important factor limiting the brightness of conventional sources are aberrations in the electron source or gun. These can often reduce the brightness by many orders of magnitude. In order to remedy these aberrations and produce a source which exploits the intrinsic brightness of a field emitting nanotip, a new extraction geometry has been designed which for reasons which will become apparent is known as proximity extraction. This method uses nanoscale geometries coupled with extremely high electric fields so that the electrons travel only a small distance from the tip before they are formed into an almost parallel beam which has a brightness (when corrected for energy) equal to the intrinsic field emission brightness. Thus almost all tip aberrations are eliminated. This is again the concept of directly imaging the nanotip emission sites which can be achieved because of the reduction in scale and the high-field extraction technique which prevents lateral expansion of the beam.

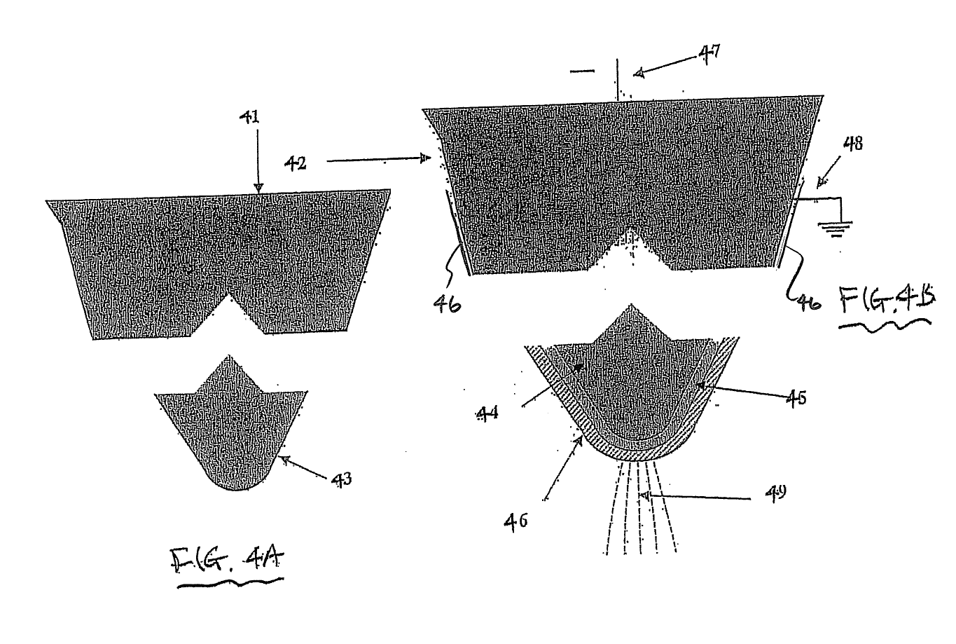

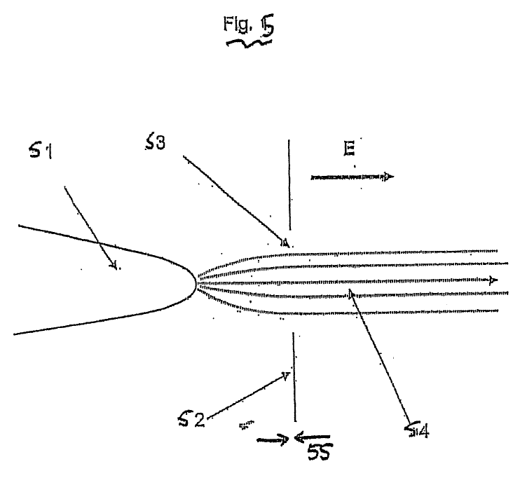

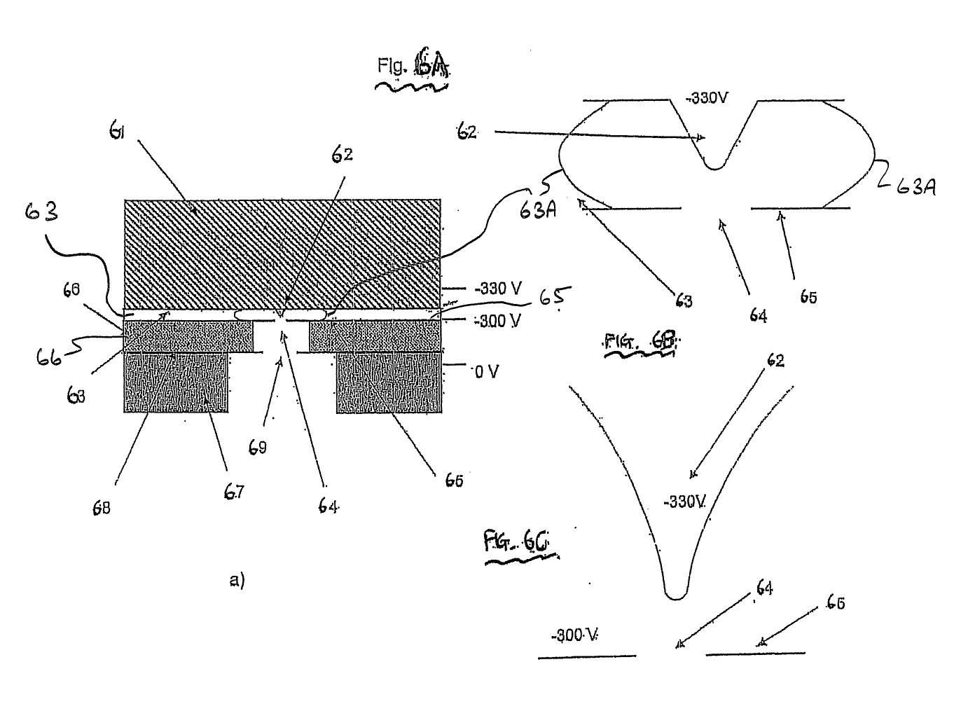

The new source geometry is shown in FIGS. 5 and 6A, B, C, with FIG. 5 illustrating the principles on which it works while FIGS. 6A, B, C show how it can be implemented in practice. In FIG. 5 the electrons are emitted from a typical nanotip 51 positioned in front of an aperture 53 in a conducting plate 52 whose thickness 55 varies from 10 nm to 500 nm depending on the aperture diameter. The nanotip would have a typical radius, or sharpness, of 5 nm and be positioned about 30 nm from the aperture 53, which has typically a 30 nm diameter but can be as large as 500 nm if the thickness of the electrode, 52, is increased. These dimensions are around 100 times smaller than in existing extraction systems. This arrangement can now be manufactured by using recent advances in MNEMS (micro-nano engineered systems) and particularly FIB (focussed ion beam) milling machines. If sufficient negative voltage is applied between the tip and layer then electrons 54, will be emitted in a beam as shown.

The expansion of this beam can be controlled by applying a very high electric field immediately after the aperture as labelled by the letter E, where the arrow denotes the direction in which the electrons are accelerated by the field and which is the reverse of the actual field direction. The effect of this field is to accelerate the electrons which, coupled to the lens effects of the aperture, constrain the beam to a maximum diameter of approximately 100 nm. This beam is now accelerated over a length from 1 to several microns depending on the requirements of the final energy. This differs quite considerably from a conventional extraction system in that there is no real image of the tip formed at some point beyond the thin film, 52 downstream of the electron beam. Rather there is a magnified virtual image behind the tip which is further left of the tip as defined in FIG. 5. The brightness of the beam at a few microns distance form the nanotip is only determined by the properties of the emission sites (size and emission angle) and can be up to a million times larger than from a conventional macroscopic source.

Using this system there are virtually no aberrations because the lateral beam expansion is small and the beam in the field continues to increase its brightness because of the increase in energy. In the normal point to point imaging as in existing sources the beam may expand laterally up to a thousand times larger than this, usually in non uniform fields, so that the system will suffer from aberrations. These aberrations effectively degrade the brightness of the source and it is not possible to focus the beam to obtain high resolution by directly imaging the emission sites. In such cases, the beam has to be severely collimated and the final lens images an illuminated collimator downstream from the source. In the embodiment shown in FIGS. 6A, 6B, 6C, the beam is not collimated at all and so there is no spurious scattering or diffraction.

A method of implementing this concept in practice is shown in FIGS. 6A, 6B, 6C. The nanotip 62 is either an integral part of the conducting substrate, 61, as shown in FIG. 6B or it can be a separate larger nanotip as shown in FIG. 6C. For the latter case the nanotip needs to be electrically connected to the substrate. The nanotip is separated from a conducting layer 65 (an aperture plate 65), by an insulating layer 63, which is etched out to expose the nanotip in front of the aperture, 64. Typically the thin conducting layer 65, might be around 50 nm thick for a 30 nm diameter aperture and 200 nm thick for 300 nm aperture and by preference an inner wall 63A of the insulating layer 63 between the substrate 61 and conducting layer 65 has a concave conical profile in cross-section as shown in FIG. 6B. Such a profile assists in reducing an amount of edge scattering. An alternative way is have a separate nanotip and position it using nano-positioning equipment on the axis of the hole, 64, at the correct distance. This can be achieved most easily if the nanotip is formed at the end of a cantilever. Conducting layer 65 may be referred to as an aperture plate 65 or knife-edged member 65.

This aperture can be produced using a FIB. A lightly doped semiconducting (or insulating) layer 66 of about one micron in thickness is then used to separate the aperture plate 65 from the conducting plate 68 which is formed on a conducting support structure 67. Typical voltages which produce a high brightness beam at 330 eV (electron volts energy) are shown on the side of FIG. 6A. Thus the nanotip is at 330 V and the 30V between it and the aperture plate 65, are sufficient to produce around 50 nA of electron current from the tip. The electric field to confine and accelerate the beam is generated by the 300 V between the aperture plate 65 and the support 67. The hole in the semiconducting (or insulating) layer, 66, is larger than the aperture by at least a factor of 3. (It can be up to 1 micron in diameter). Plate, 68, is a thin layer of similar thickness to the aperture plate 65 and has a central aperture 69 of between 100 and 300 nm diameter. If the aperture plate 65 is relatively thick then it is preferably made with a conical shape so that its edge is only a few nanometres thick.

Although the source is designed so as that the beam does not intercept aperture plate 65 or plate 68 it is preferable that any edge scattering by edges of plate 68 are reduced to a minimum. A similar consideration applies to the aperture plate 65. The conical hole in this plate must have the larger diameter of the cone adjacent to the high field region especially for this aperture. Thus the diameter of the hole will be 30 nm but can be as large as 500 nm. Although the beam calculations suggest that the beam is well clear of the aperture edges, increasing the size of the two apertures 64, 69, to several hundred nanometers ensures that there is no scattering and the effects of image charges and diffraction are negligible.

The overall brightness of the beam emitted from the exit aperture 69 can be many orders of magnitude greater than that from a more conventional source. It can be increased by another order of magnitude if supertips are used.

The present invention further extends to apparatus and analytical methods comprising a particle beam generator and sub-miniature microscope of the type disclosed in patent document WO 03/107375, modified or enhanced as described above, and used in measuring the energy and intensity of scattered electrons so as to be able to identify atomic species under examination; for making the resolution of the instrument smaller than the focused beam spot; and for directly measuring the micro-nano crystalline structure of materials.

Referring to FIG. 6D, and having regard to FIG. 3C and the description thereof, the performance of the instrument is limited by the size of the electron emission site and since there are now several reports of the manufacture of stable atomic sized emitters (supertips) it can be shown that this microscope modelled in FIG. 3C will have resolution of the order of 2 Å. However, what is important is that the microscope is matched to the electron emission site since the size of this will vary according to the applied field. Thus atomic emitters (supertips) produce a few nanoamps of current at applied fields much lower than that for typical nanotips. This lower field can be achieved by reducing the voltage on the tip and/or moving the tip further from the entrance aperture. FIG. 6C shows the field at a nanotip of radius 5 nm for varying voltages, V1 between the tip and the aperture plate 65 at a distance of 30 nm and for a fixed einzel lens voltage of −380V. In all cases the position of the focus can be varied with subsequent change in the beam spot size with the unit magnification point being at around 4 μm from the end of the einzel lens where u/v=1.

The practical geometry for making measurements using this microscope is not as convenient as a high energy microscope because of the very short focal length. The simplest methodology is to construct the microscope at the end of a microtip which can be positioned at the required focal distance from the sample.

This geometry ensures that the back-scattered electrons can be detected whilst the scanning can be achieved by moving either the sample or the microscope using conventional piezo devices. This is entirely analogous to a conventional SEM with the SEM nanotip being replaced with a focused electron beam. However because the depth of field is large (50 nm) then the distance of the microtip to the sample is easier to maintain during scanning and one can, in addition, adjust the voltage on the lens to maintain a focus. This means that the speed of scanning with will be significantly faster than a STM and, at the highest resolution, should be greater than a conventional SEM because the beam current is 100 times larger.

Finally it is worthwhile noting the advantages which arise from the ability to focus low energy electrons to atomic dimensions. Firstly the instrument is considerably simpler and does not require high voltages so that the overall packaged size will therefore resemble an STM. However the most important aspect is that the elastic scattering cross-section is much larger than at the higher energies of conventional instruments and will allow one to image atoms and identify atomic species from the elastic scattering alone (the most intense channel) since the cross-section for this scattering varies as the square of the atomic number. Furthermore it is possible to generate a nanotip from tungsten wire and hence generate polarized electrons for magnetic studies of surfaces. Also, since this energy is within the low energy electron diffraction (LEED) regime it would appear that it is now possible to directly sequence a single strand of DNA from the forward and backward diffraction pattern when the beam is focussed to a few nanometres and is then scanned laterally along the strand. (It may be necessary to use two beams or rotate the strand to avoid masking by the spiral polymer chain.) Using LEED to unravel the structure of a single protein molecule is more difficult since multiple scattering will predominate. However it may be feasible to measure the surface topography of a single protein molecule if the electron energy is below 100 eV and the protein is rotated in the beam. The latter can be achieved by tagging a fluorescent dye to the protein and holding it using a linearly-polarised, standing-wave laser beam, particularly if the molecule is sufficiently laser-cooled. For the DNA sequencing the electron beam is focussed to a diameter of 2-3 nm and because the beam is effectively coherent it is possible to make a hologram of the base pairs in the beam. However for a rapid sequencing it will only be necessary to obtain a signature in the diffraction pattern from several detectors positioned around the focal spot as the beam is scanned along the strand. The radiation damage cross-section for double strand breaks is much smaller than the elastic scattering channel particularly if the electron energy is less than 50 eV so that a (rapid) scan rate which does not produce double-strand breaks and yet provides sufficient ‘fingerprint’ data is almost certainly possible even though the wavelength at this energy prevents the generation of a full hologram. (It should be noted that the positional stability of the DNA is not critical since the density of electrons at electrical currents of the order of nanoamps is extremely low so that the movement during the passage of a single electron is much smaller than 1 Å. The beam width must therefore be significantly larger than the diameter of the DNA strand.

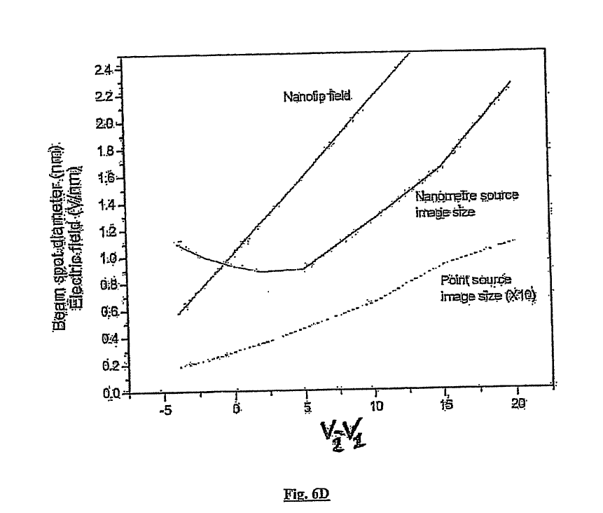

In this further description, reference is had to FIGS. 7-10, in which a microscope comprises a Scanning Electron Microscope (SEM) on-a-chip 70.

The SEM comprises a nanotip electron source, 72, an electron extractor/accelerator, 73, and an electrostatic lens (or lenses), 74, to focus the beam, 76, down from a diameter less than 100 nm, to a spot, 78, of size around 0.1 nm. To obtain this small spot size it is essential that the last lens has a focal length around 10 microns. The SEM chip is formed, or mounted, on the end of a tapered microtip chip-body 81, so that the path of the scattered electrons is not obstructed from a material surface. The tapered chip-body 81 is preferably formed from a single piece of silicon wafer, but the reader will appreciate that the chip-body may alternatively be formed from other suitable materials. The chip-body 81 comprises integrated electronics to control the microscope. Such integrated control means may be fabricated within the chip-body. The chip body is attached to a nano-manipulator, 81A, of the type often used with scanning tunnelling microscopes. This can accurately position the microscope both laterally and vertically above a sample of material 79. Electrical connections to the microscope are made through the chip body 81. Scanning can be achieved using the nano-manipulator 81A or alternatively the sample 79 may be moved using piezo raster scanning whilst measuring the intensity of the scattered electrons, 77, using electron detectors such as, for example, electron channel plates.

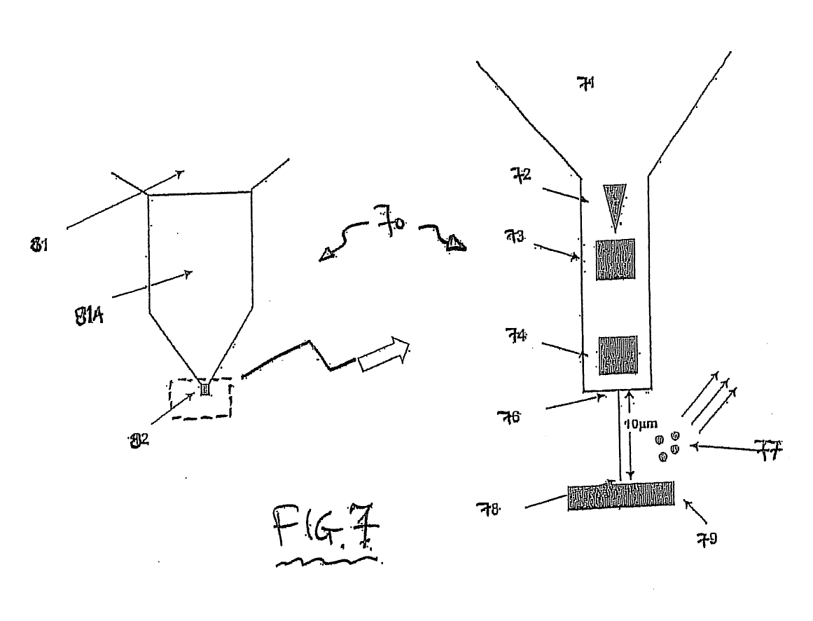

Referring to FIG. 8a, the microscope may be adapted to simultaneously measure the scattered electron intensity and energy. In this system an electrostatic separator 83, such as, for example, a hemispherical double focussing electrostatic separator (but shown in FIG. 8a as a simple pair of plates), is used to separate the different energy electrons and disperse them along a position sensitive detector 84. The detector 84 may be any one of a number of known types such as, for example, a channel plate with a resistive collector. The ratio of the currents which flow through path A and B, determines the position of the incident electron and hence from the characteristics of the electrostatic separator determines its energy. A typical electron energy spectrum is shown in FIG. 8b. This consists of an elastic peak 86, at the energy of the focussed electron beam and a broader diffuse region 87, which is the inelastic scattered electrons which are mostly from electrons which penetrate the surface. The intensity of this latter broad region, as a function of the electron beam position, will yield the topography of the surface whilst the intensity in the elastic peak 86, can be used to obtain the atomic number (the atomic species) of any atom in the image. The image of the surface atoms is obtained from the intensity of the scattered electrons as a function of the electron beam position on the surface. The sensitivity of this discrimination, particularly for heavier elements can be improved by scanning the electron energy across the L or M edges of the atom in question. The elastic peak will show a dip at the L and M binding energies which is characteristic of the atomic number of the atom in question, as shown in FIG. 8c. Scanning of the energy is best achieved by negatively biasing (positive for reducing the energy), the whole microscope with a variable voltage, as shown at 88, so that the energy of the electrons is increased relative to the sample. In this way an energy range from 100 ev to 1000 ev can be covered and this encompasses most of the L and M atomic edges. An accurate determination of the energy position of the edges which are dips in the spectrum, as shown, also provides information about the chemical bonding of the element particularly when it refers to the valence electron shell.

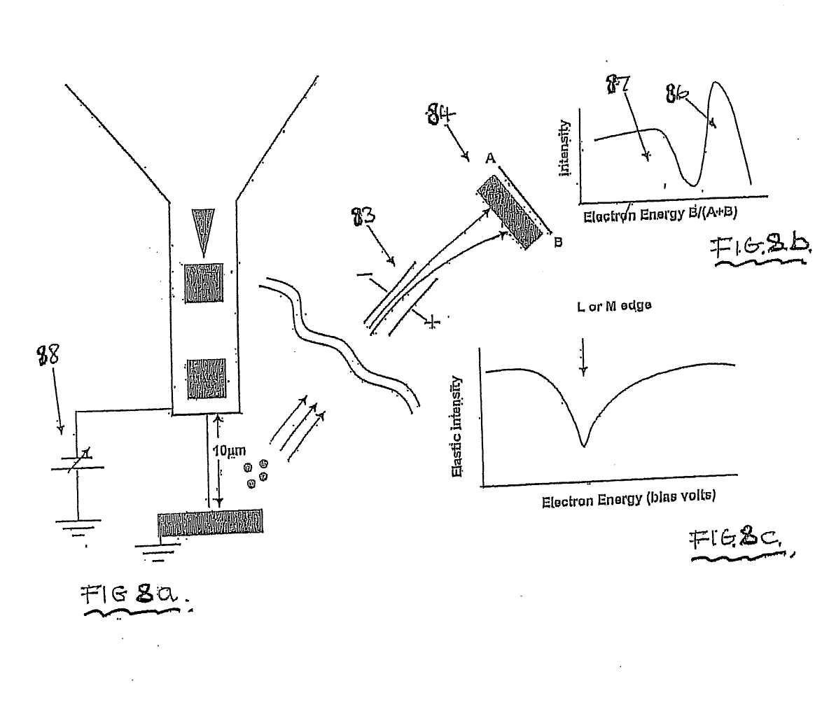

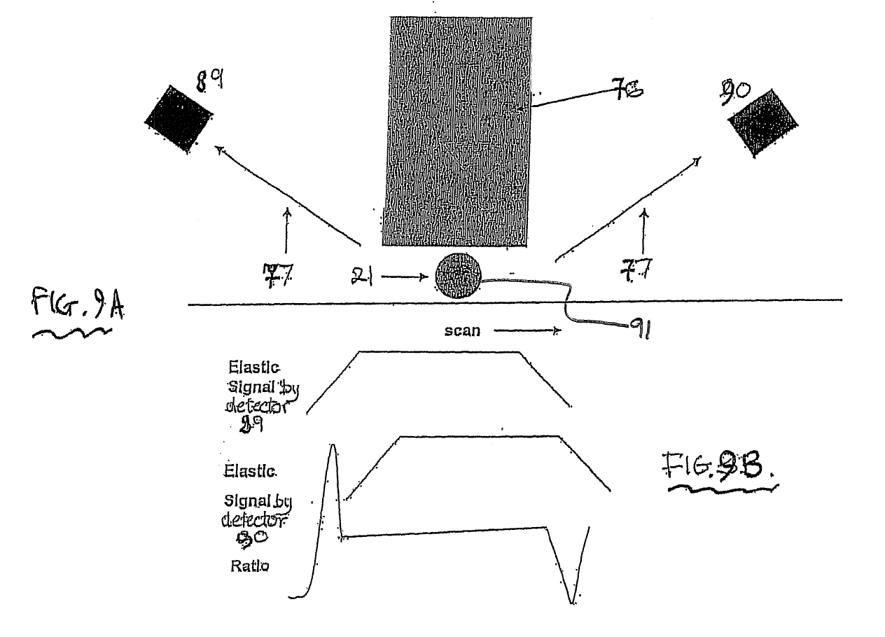

Referring to FIG. 9a, an arrangement is shown to improve the resolution of the instrument by providing a system of “near-side far-side” scattering. Two energy sensitive detectors, 89 and 90, are positioned on either side of the direction of the scan of the microscope or material sample. As the beam 76 moves across the surface of the sample (from left to right in the drawing), the signal from electrons 77, elastically scattered from an atom 91, is first detected by detector 89 and then by detector 90. As the scan continues the signal detected by detector 89 disappears before the signal detected by detector 90. The ratio of the two signals from a square profile beam as shown in FIG. 9b and can be used to construct an image of the atom with greater resolution than the beam spot size.

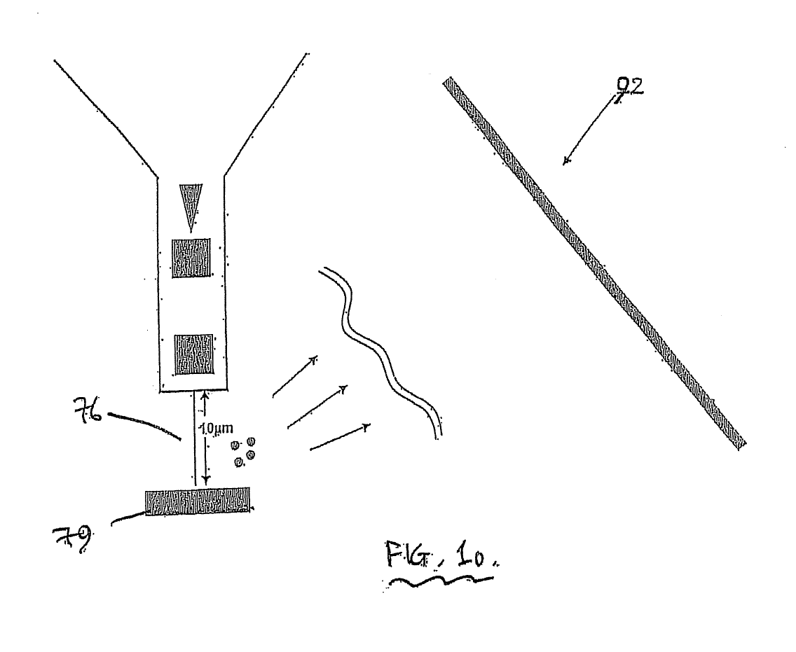

Referring to FIG. 10, an arrangement is shown for carrying out low energy electron diffraction with a focussed electron beam 76. In this arrangement a series of detectors (or an electron fluorescent screen) 92 is used to measure the diffraction of electrons from nano-crystals (or micro-crystals) in the surface of the sample material 79. The beam is now defocused so that the beam spot is the same size, or smaller than, the nanocrystal sizes in the surface so the diffraction pattern is generated by interference of the electrons scattered from the individual atoms in the nanocrystals. In this way it is possible to study the nature of the polycrystalline surface structure. As mentioned above, more information about the crystal structure may be gained by varying the energy using a similar biasing arrangement 88 as shown in FIG. 8a. A range of energies from 50 eV to 1000 eV is possible.

In a particularly preferred embodiment, the nanotip may be a supertip made by lithography using electron beams and organometallic vapours, i.e. the manner in which a nanotip may be made using a focussed ion beam (FIB).

For instance, prior art reference [1535, J. Vac. Sci. Technol. B15(4), July/August 1997] indicates that materials machining using a Scanning Tunnelling Microscope (STM) is hindered by poor linewidth compared to the atomic resolution power of the microscope itself. The trace of the emitted beam is widened due to electron or ion field emission from many tip locations having a low work function. A preferable solution is to use a supertip which provides a single site that delivers a beam in a confined emission angle. The supertip consists of a blunt base tip and an attached supertip of a few nanometers in diameter and height. The supertip delivers the current from one point of field instability only. The attached minaturised tip generates the high field required for field emission. Electron beam-induced deposition from organometallic gold compounds and a heated substrate is used to build the attached nanocrystalline supertip. Confinement of the emission angle of the emitted beam is confirmed by field emission microscope investigations. An angular confinement of ±7.2° is obtained. Such supertips can deliver an emission of 0.2 mA/sr as measured, and have therefore at least a tenfold higher angular emission density than conventionally etched tips. Deposited supertips require no single crystalline base and can be placed on any base material. Furthermore, such supertips can successfully operate in a scanning tunnelling microscope in air.

In the case of the present invention, a supertip can work for electrons if such are periodically cleaned by reversing all the voltages. In connection with a microscope according to the present invention and employing a supertip, the reversal of the voltages on the microscope operating in a low pressure inert gas (e.g. Ar, Xe) environment will allow for the focussing of ions (produced by field ionization at the tip) down to atomic dimensions. Furthermore, such an arrangement will not suffer from breakdown because the sizes are so small that an avalanche will not form because the mean free path of the electrons will be comparable to the size of the arrangement (including the focal length).

The arrangement described above has potentially revolutionary applications, such as in-situ nanocrack identification for the aircraft industry.

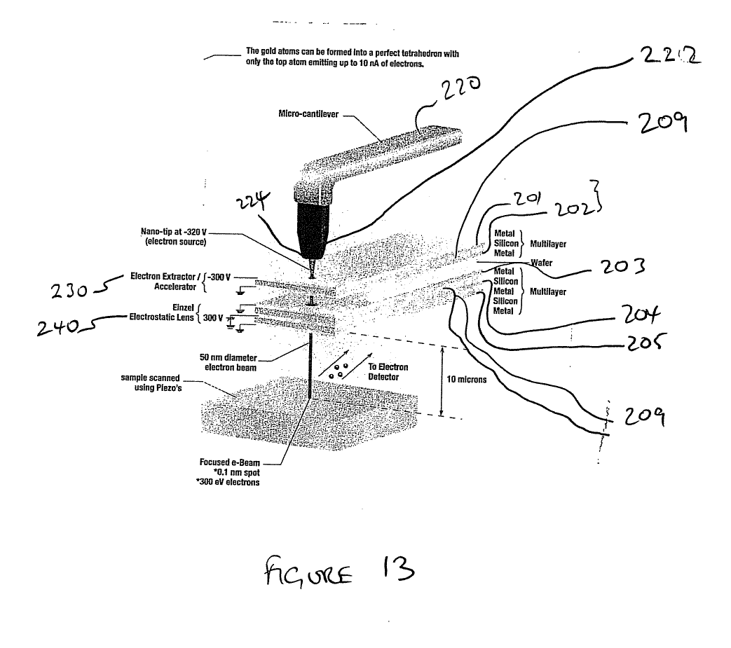

FIG. 13 shows a schematic view of a microscope according to an embodiment of the invention. The microscope has a micro-cantilever 220 having a tip portion 222 having a nanotip 224 formed at an extreme end of the tip portion 222.

An electron extractor/accelerator portion 230 is provide in juxtaposition with the nanotip 224, the portion 230 having a first electrode 201 and a second electrode 202 sandwiching a layer of silicon 209.

In use, in some embodiments the first electrode 201 (being an extractor plate) is held at a potential of around −300V whilst the second electrode 202 is held at earth potential.

A focusing portion 240 has three electrodes separated by respective layers of silicon 209. The first and third of these three electrodes being a third and fifth electrode of the microscope 203, 205, respectively are held at earth potential whilst the middle electrode being a fourth electrode 204 of the microscope is held at a potential of around 300V.

A layer of silicon is provided between the extractor/accelerator portion 230 and focusing portion 240.

In use the fifth electrode 205 is positioned a distance of around 10 μm from a surface of a sample which is scanned beneath the sample in a generally flat plane. In some embodiments the sample is scanned such that a local height of the sample is at a generally constant distance below the fifth electrode 205. Piezo-electric scanning elements may be used to this effect.

In some embodiments the microscope is configured so that the electron beam has a diameter of around 50 nm as it leaves the fifth electrode, the beam being focussed to a size of around 0.1 nm at an energy of 300 eV at the sample surface.

An electron detector is provided to detect electrons emerging from the sample due to irradiation by the electron beam.

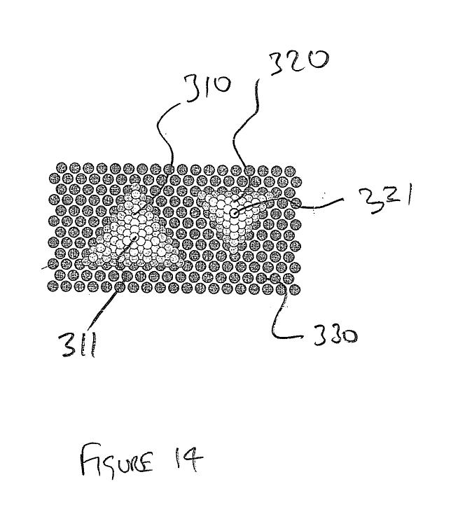

FIG. 14 shows a pair of nanopyramidal tips 310, 320 formed on a substrate 330. The tips 310, 320 have a single atom at apices 311, 321 of each structure thereby providing an atomically sharp tip as an electron emission site. In the structures shown the substrate is gold (Au) and the nanopyramids also formed from gold. Other metals are useful as described above.

In some embodiments of the invention, a tip having atomic dimensions is crucial to achieving images having atomic resolution. This is because in a microscope having unit magnification of the electron beam between the tip and the sample, an electron beam of atomic dimensions will irradiate the sample allowing images of atomic resolution of near-atomic resolution to be obtained provided aberrations are small.

1. A particle beam generator comprising:
particle extraction means disposed adjacent a particle source and operable to extract particles from such a source into an extraction aperture of the extraction means to form a particle beam,
particle accelerating means operable to accelerate the extracted particles to increase the energy of the beam, and
focussing means operable to focus the particle beam,
each of said extraction means, accelerating means and focussing means being arranged in sequence and having apertures therethrough and in alignment to define a passageway through which the particles are constrained to move,
characterised in that the extraction means comprises a lens structure comprising at least a pair of electrodes separated by a layer of insulating material allowing the application of different potentials to each of the lens structure electrodes, one of said electrodes comprising an extraction plate having an extraction aperture formed therein, the extraction plate being arranged whereby particles may be drawn from the particle source and through the extraction aperture by means of a potential difference between the particle source and said extraction plate.

2. A generator as claimed in claim 1 wherein the focussing means comprises an Einzel lens structure having an overall length of the order of from around 1 to around 10 microns.

3. A generator as claimed in claim 1 wherein the extraction means comprises a nano-scale Einzel lens structure (NEZL) having an overall length of no more than 500 nm.

4. A generator as claimed in claim 1 wherein the extraction means comprises two electrodes.

5. A generator as claimed in claim 1 wherein the extraction means comprises three electrodes.

6. A generator as claimed in claim 3 wherein the NEZL structure comprises said extraction plate.

7. A generator as claimed in claim 3 wherein the extraction plate is provided between the particle source and the NEZL structure.

8. A generator as claimed in claim 7 wherein the NEZL structure is provided sufficiently close to the extraction plate to have an immediate influence on particles extracted from the particle source by the extraction plate.

9. A generator as claimed in claim 1 wherein the focussing means comprises primary and secondary focussing means, each of said extraction means, accelerating means and primary focussing means being arranged in sequence, the secondary focussing means being disposed remotely from an end of the primary focusing means such that said primary and secondary focussing means are essentially separated, the secondary focussing means having an average aperture having a size that is greater than that of the primary focussing means.

10. A generator as claimed in claim 9 wherein the secondary focussing means comprises alignment means for aligning the secondary focussing means coaxially with said primary focussing means.

11. A generator as claimed in claim 10 wherein the alignment means comprises a nanopositioning member operable to achieve coaxiality between the primary and secondary focussing means to within 10 nm, preferably 1 nm, and most preferably to within 0.1 nm.

12. A generator as claimed in claim 9 wherein a first electrode of the secondary focussing means being an electrode of the secondary focussing means closest to the primary focussing means is provided with a knife-edged opening aperture arranged to collimate a particle beam arriving thereat.

13. A generator as claimed in claim 12 wherein a diameter of said knife-edged opening aperture of the secondary focussing means is greater than a diameter of a particle beam aperture of the primary focussing means.

14. A generator as claimed in claim 9 wherein a first electrode of the secondary focussing means being an electrode of the secondary focussing means closest to the primary focussing means is arranged to have a diameter greater than that of a beam of electrons arriving at the secondary focussing means from the primary focussing means.

15. A generator as claimed in claim 14 wherein the first electrode of the secondary focussing means has a diameter of at least substantially 2 μm.

16. A generator as claimed in claim 1 wherein the particle source comprises a nanotip member.

17. A generator as claimed in claim 16 wherein the nanotip member has a tip portion having a free end having a diameter of from around 1 atomic diameter to around 50 nm.

18. A generator as claimed in claim 16 wherein the rip portion is in the form of a nanopyramid structure or similar stable electron emitter structure of atomic or substantially atomic dimensions.

19. A generator as claimed in claim 16 wherein the nanotip member comprises at least a portion in the form of a length of wire.

20. A generator as claimed in claim 17 wherein the tip portion is formed from at least one selected from amongst platinum, tungsten, platinum iridium alloy, cobalt, gold and silver.

21. A generator as claimed in claim 17 wherein the tip portion is formed of a material configured to be resistant to reaction with oxygen.

22. A generator as claimed in any preceding claim 1 wherein the extraction aperture has a diameter of from around 1 nm to around 10 μm, preferably from around 1 nm to around 1000 nm, more preferably from around 2 nm to around 20 nm.

23. A generator as claimed in any preceding claim 1 wherein the accelerating section is arranged to accelerate particles from said particle source by generating an electric field of a value whereby a diameter of the particle beam is substantially constant along a length of the accelerating section, the diameter of the beam being substantially equal to a diameter of said extraction aperture.

24. A generator as claimed in any preceding claim 1 wherein the accelerating section is arranged to accelerate particles from said source by means of an electric field having a value of from around 100 to around 1000V/μm.

25. A generator as claimed in claim 1 wherein the particle source is configured to provide a source of one selected from the group consisting of electrons and ions.

26. (canceled)

27. A particle beam generator comprising
particle extraction means disposed adjacent a particle source and operable to extract particles from such a source into an extraction aperture within said extraction means to form a particle beam,
particle accelerating means operable to accelerate the extracted particles to increase the energy of the beam, and
primary focussing means operable to focus the particle beam,
each of said extraction means, accelerating means and primary focussing means being arranged in sequence and having apertures therethrough and in alignment to define a passageway through which the particles are constrained to move,
characterised in that the particle generator further includes a secondary focussing means disposed remotely from the end of the primary focusing means such that said primary and secondary focussing means are essentially separated, the secondary focussing means having an average aperture size which is greater than that for the primary focussing means.
